(19) United States
(12) Patent Application Publication
(10) Pub. No.: US 2010/0189929 A1
(43) Pub. Date: Jul. 29, 2010

(54) COATING DEVICE AND DEPOSITION APPARATUS

(76) Inventors: James W. Neal, Ellington, CT (US); Michael J. Maloney, Marlborough, CT (US); David A. Litton, West Hartford, CT (US); Christopher Masucci, Coventry, CT (US)

Correspondence Address: CARLSON, GASKEY & OLDS/PRATT & WHITNEY, 400 WEST MAPLE ROAD, SUITE 350, BIRMINGHAM, MI, 48009, US

(21) Appl. No.: 12/360,966

(22) Filed: Jan. 28, 2009

(51) Int. Cl. C23C 14/30; C23C 14/00

(52) U.S. Cl. 427/585; 118/723 EB

(57) ABSTRACT

A coating device for use with an electron beam vapor deposition apparatus includes a crucible portion and a nozzle portion. The crucible portion includes a gas inlet port, a heating zone for presenting a source coating material to be heated, and a flow passage exposed to the heating zone and fluidly connected with the inlet port. The nozzle portion of the coating device includes an outlet orifice fluidly connected with the flow passage for jetting a coating stream from the coating device.

### BACKGROUND OF THE INVENTION

This disclosure relates to coating equipment and, more particularly, to a coating device and deposition apparatus that facilitates depositing a coating material on surfaces of a substrate.

Physical vapor deposition (“PVD”) is one common method for coating a substrate, such as gas turbine engine airfoils. For instance, the coating may be a protective coating or a coating for promoting adhesion. One type of PVD process utilizes an electron beam gun to melt and vaporize a source material in a crucible. The vaporized source material deposits onto the substrate. Although effective, angled surfaces and non-line-of-sight surfaces relative to the crucible may be poorly coated or not coated at all.

### SUMMARY OF THE INVENTION

An example coating device for use with an electron beam vapor deposition apparatus includes a crucible portion and a nozzle portion. The crucible portion includes a gas inlet port, a heating zone for presenting a source coating material to be heated, and a flow passage exposed to the heating zone and fluidly connected with the inlet port. The nozzle portion of the coating device includes an outlet orifice fluidly connected with the flow passage for jetting a coating stream from the coating device.

The coating device may be part of an electron beam vapor deposition apparatus that includes a coating chamber, a coating zone within the coating chamber for coating work pieces, at least one electron beam source for evaporating a source coating material, and a gas source for selectively providing a carrier gas to the coating device.

An example method for use with an electron beam vapor deposition apparatus includes emitting electron beams from an electron beam source onto a source coating material within a crucible portion of a coating device to evaporate the source coating material. Evaporated source coating material is entrained in a carrier gas to provide a coating stream. The coating stream is jetted toward a coating zone from an outlet orifice of a nozzle portion of the coating device.

### BRIEF DESCRIPTION OF THE DRAWINGS

The various features and advantages of the disclosed examples will become apparent to those skilled in the art from the following detailed description. The drawings that accompany the detailed description can be briefly described as follows.

FIG. 1 illustrates selected portions of an example deposition apparatus.

FIG. 2 illustrates an example of a coating device for use with the deposition apparatus.

FIG. 3 illustrates an example of the operation of the coating device.

FIG. 4 illustrates another example coating device for use with the deposition apparatus.

FIG. 5 illustrates another example coating device for use with the deposition apparatus.

### DETAILED DESCRIPTION OF THE PREFERRED EMBODIMENT

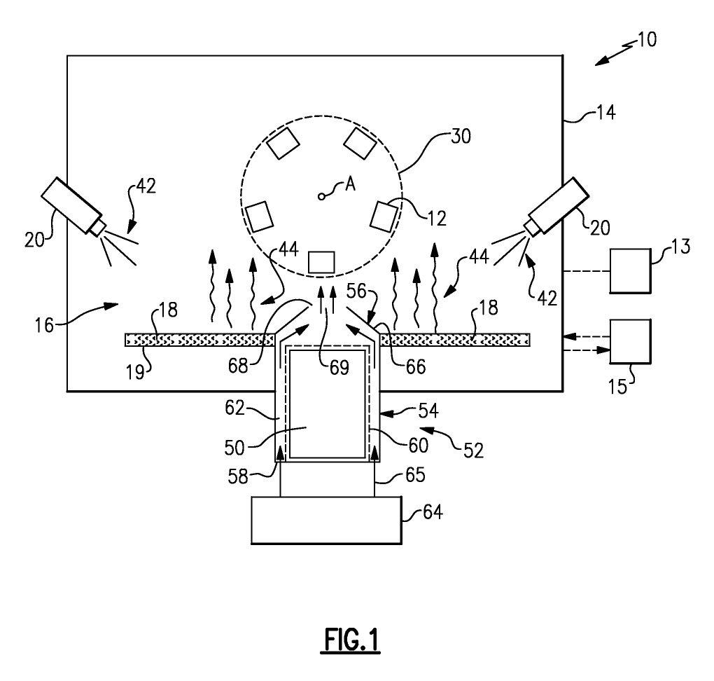

FIG. 1 illustrates selected portions of an example deposition apparatus 10 for depositing a coating on one or more work pieces 12 via electron beam directed vapor deposition (“EBDVD”). The example deposition apparatus 10 is adapted for EBDVD; however, it is to be understood that other types of deposition equipment and physical vapor deposition processes may also benefit from the disclosed examples. Additionally, the work pieces 12 are not limited to any particular type. For instance, the work pieces 12 may be gas turbine engine components, such as airfoils (e.g., blades and vanes), or other components.

The type of coating deposited may be any desired coating that is suitable for vapor deposition, such as a metallic coating or a ceramic coating. In one example, the coating is a ceramic thermal barrier coating that includes gadolinia, zirconia, yttria, or combinations thereof. For instance, the ceramic is gadolinia stabilized zirconia, yttria stabilized zirconia, or a multi-layer combination. In a further example, the ceramic thermal barrier coating includes about 59 wt % of gadolinia and a balance of zirconia. The term “about” as used in this description relative to compositions or other values refers to possible variation in the given value, such as normally accepted variations or tolerances in the art.

In the illustrated example, the deposition apparatus 10 includes a coating chamber 14 for containing the work pieces 12. For instance, the coating chamber 14 may be a vacuum chamber and may include various ports for evacuating the interior of the coating chamber 14 or for selectively introducing gases that are to be used in the coating process. For instance, a gas source 13 provides a desired flow of oxygen or other gas. Optionally, a pump 15 may circulate a coolant (e.g., water) through walls of the coating chamber 14 to control wall temperature.

A heating source 16 may be located within the coating chamber 14 to heat the work pieces 12 to an oxidation temperature for a pre-heating stage. For instance, the work pieces 12 may include a nickel alloy substrate and a bond coat on the substrate. The bond coat may include MCrA1Y, where the M includes at least one of nickel, cobalt, iron, or a combination thereof, Cr is chromium, Al is aluminum, and Y is yttrium.

The work pieces 12 may be pre-heated at the oxidation temperature to form a thermally grown oxide on the bond coat that enhances adhesion of ceramic thermal barrier coatings to the work pieces 12.

In the disclosed example, the heating source 16 includes a media 18 that may be used to radiate heat and heat the work pieces 12 to the oxidation temperature. The media 18 may be any type of media that radiates heat. For instance, the media 18 may include particles of a ceramic material in a water-cooled tray 19. In one example, the ceramic material composition is equivalent to the composition of the coating that is to be deposited onto the work pieces 12 to avoid contaminating the work pieces 12 with foreign substances. In other examples, the heating source 16 may be a resistance heater or other type of heater.

At least one electron beam source 20, such as an electron gun, is mounted relative to the coating chamber 14 for pre-heating the media 18 and for depositing the coating. The disclosed example illustrates two electron beam sources 20, which may be used for pre-heating the media 18, applying the coating, or both. However, given this description, one of ordinary skill in the art will recognize that a single source or additional sources may be used to meet the needs of a particular application or coating process.

The work pieces 12 are mounted within a coating zone 30 in the coating chamber 14. For instance, the coating zone 30 is the spatial volume where the work pieces 12 will be coated. The work pieces 12 may be mounted in the coating zone 30 using a mounting fixture, such as a cylindrical fixture.

The electron beam sources 20 may be activated to emit electron beams 42 onto the media 18. The electron beams 42 heat the media 18 and produce radiant heat 44 that radiates toward the coating zone 30. For example, a controller (not shown) may utilize software, hardware, or both to control focus, filament current, scanning area (power density), and/or other parameters of the electron beam sources 20 along with other operations associated with the deposition apparatus 10 (e.g., gas flow) to provide a desired amount of heat before and/or during the coating process. The electron beam sources 20 may also raster relatively low current-density electron beams 42 across the work pieces 12 prior to or during coating to directly heat the work pieces 12.

In the coating process, the electron beam sources 20 may be activated as described above to emit electron beams 42 onto an ingot 50 serving as the source material for coating the work pieces 12. The deposition apparatus 10 presents the ingot 50 into the coating chamber 14 using a coating device 52. Although only one coating device 52 is shown, the coating chamber 14 may utilize multiple coating devices 52 and corresponding multiple ingots 50.

The coating device 52 includes a crucible portion 54 and a nozzle portion 56 for facilitating deposition of the coating. The crucible portion 54 includes a gas inlet port 58, a heating zone 60 for presenting the ingot 50, and a flow passage 62 exposed to the heating zone 60. The flow passage 62 is fluidly connected with the gas inlet port 58. The gas inlet port 58 may be a connector fitting or the like for connecting the coating device 52 with a gas source 64 for selectively providing a carrier gas 65, such as an inert gas.

The nozzle portion 56 includes a funnel 66 having an outlet orifice 68 fluidly connected with the flow passage 62 for jetting a coating stream 69 from the coating device 52. The coating stream 69 includes vaporized source material from the ingot 50 entrained in the carrier gas 65. As will be described in greater detail below, the carrier gas 65 flows over the ingot 50 as the ingot 50 evaporates. The carrier gas 65 entrains vaporized source coating material from the ingot 50 to produce the coating stream 69. The coating stream 69 flows through the funnel 66 and jets from the outlet orifice 68 toward the coating zone 30 (e.g., directed vapor deposition) to deposit the source coating material on the work pieces 12.

Referring also to FIG. 2, the example outlet orifice 68 may have a rectilinear cross-section. That is, the outlet orifice 68 may have a cross-sectional area formed with at least one straight line side. In the illustrated example, the outlet orifice 68 has a rectangular cross-section with four straight line sides. However, in other examples, the cross-section of the outlet orifice 68 may be circular, oval, or another polygonal shape having any desired number of straight line sides. Given this description, one of ordinary skill in the art will be able to recognize cross-sectional shapes of the outlet orifice 68 to meet their particular needs.

The crucible portion 54 may have any suitable shape for presenting the ingot 50. In the illustrated example, the crucible portion 54 includes four planar side walls 72 (two shown) arranged in a parallelogram. In other examples, the crucible portion 54 may include fewer or additional side walls that are geometrically or non-geometrically arranged, a curved side wall, or combinations thereof.

The funnel 66 of the nozzle portion 56 may include one or more sloped walls 74 that extend between the crucible portion 54 and the outlet orifice 68. For example, there may be one sloped wall 74 corresponding to each planar side wall 72 of the crucible portion 54, a sloped wall 74 with curved corners, or a combination thereof. In the example shown, each sloped wall 74 is connected on two opposed sides to two other respective sloped walls 74, and spans between the planar side wall 72 and the outlet orifice 68. The sloped walls 74 may be planar such that the planes are angled with respect to the planar side walls 72 to form the funnel 66.

The funnel 66 is fluidly connected with the flow passage 62 of the crucible portion 54. The reduction in cross-sectional area increases flow rate and thereby “jets” the coating stream 69 from the outlet orifice 68. The jetted coating stream 69 may be aimed at a particular portion or portions of one or more of the work pieces 12 that are to be coated.

The crucible portion 54, the nozzle portion 56, or both may be formed from any suitable type of material. In one example, the crucible portion 54, the nozzle portion 56, or both are formed from a refractory material, such as a ceramic, or an alloy material that resists the temperatures generated during the coating process. In some examples, the crucible portion 54, the nozzle portion 56, or both may be cooled structures to facilitate temperature resistance.

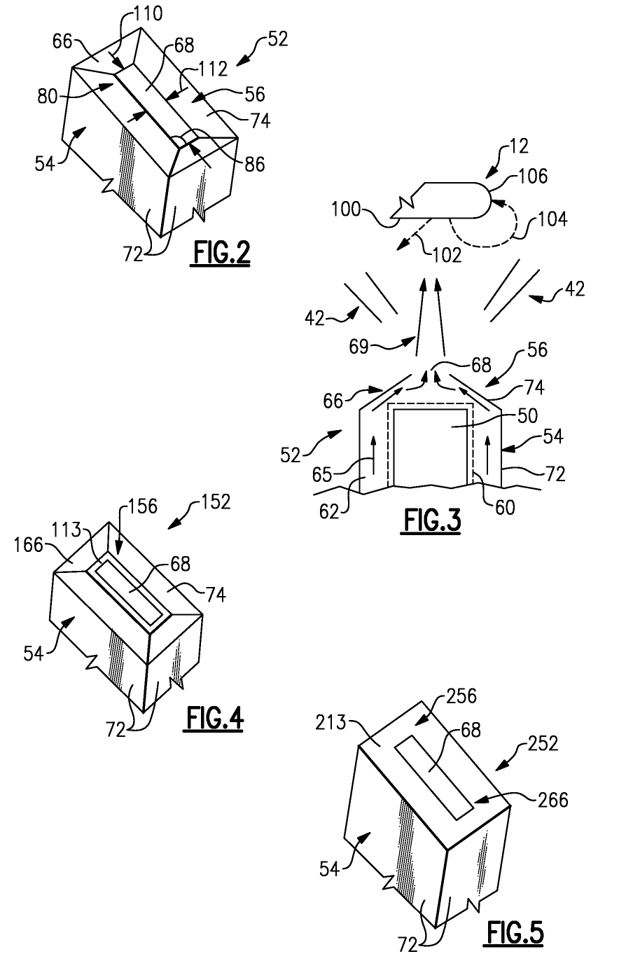

FIG. 3 illustrates an example of using the coating device 52 to facilitate coating the work piece 12. In the illustrated example, the rectilinear cross-section of the outlet orifice 68 facilitates coating transversely oriented surfaces (i.e., surfaces non-perpendicularly oriented to the flow direction of the coating stream 69) and non-line-of-sight surfaces of the work pieces 12. For instance, the straight line sides of the outlet orifice 68 meet at corners 86. The corners 86 may contribute to random collisions among the particles in the coating stream 69 from the outlet orifice 68 such that the coating stream 69 generally moves toward the coating zone 30. When the coating stream 69 impinges upon a line-of-sight surface 100 of the work piece 12, the carrier gas 65 and any undeposited ingot material may deflect off of the line-of-sight surface 100. The random collisions among the particles in the coating stream 69 randomize the direction of deflection of any undeposited ingot material. For instance, a portion of the deflected ingot material may deflect in direction 102 and another portion of the evaporated ingot material may deflect along direction 104. Thus, instead of always deflecting back toward the coating device 52, the undeposited ingot material deflects in random directions and may thereby deflect toward a transversely oriented surface or a non-line-of-sight surface, such as non-line-of-sight surface 106 of the work piece 12. The coating device 52 thereby facilitates depositing the coating on transversely oriented surfaces and non-line-of-sight surfaces.

The rectilinear cross-section of the outlet orifice 68 also provides a favorable shape of the coating stream 69. For instance, the rectilinear cross-section creates a cone-shaped flow stream that facilitates accurately directed the coating stream 69 at the work pieces 12.

Likewise, the line-of-sight surface 100 being coated may be near a corner or fillet radius, and the randomized deflection may reduce interference with the incoming coating stream 69 to facilitate coating the line-of-sight surface 100.

The coating stream 69 may also directly impinge upon and coat transversely oriented surfaces and non-line-of-sight surfaces. For instance, vaporized ingot material flowing within the coating stream 69 may flow along a curved path around an edge of the work piece 12 to impinge upon and coat a transversely oriented surface or non-line-of-sight surface that is adjacent to the edge.

Additionally, the coating device 52 may be used to facilitate forming a desired orientation of the coating on the transversely oriented surfaces and non-line-of-sight surfaces. For instance, the coating generally forms in a columnar microstructure with a columnar axis approximately parallel to the flow direction of the coating stream 69. On a line-of sight surface, the microstructural columns would be approximately perpendicular to the line-of-sight surface. Without the random collisions among the particles in the coating stream 69, the microstructural columns formed on transversely oriented surfaces would not be perpendicular to the transversely oriented surfaces. With the random collisions in the coating stream 69 though, the deflected ingot material impinges the transversely oriented surface at a steeper angle (e.g., approaching perpendicular) such that the columns would be approximately perpendicular to the surface. For example, perpendicular microstructural columns may be desirable on all surfaces for enhanced durability and strength.

The flow of coating stream 69 may be designed to achieve a desired coating effect. For instance, the example outlet orifice 68 has an aspect ratio of length 110 to width 112 that is greater than one (see FIG. 2). In some examples, the aspect ratio may be designed to provide a desired shape of the coating stream 69 to produce a desired coating effect or coating orientation Likewise, the number of straight line sides of the outlet orifice 68 or the angles of the corners 86 between the sides may be designed to influence the coating stream. Additionally, the influence of the geometry of the outlet orifice 68 may be used in combination with controlling other parameters, such as the stand-off distance between the work pieces 12 and the coating device 52, the steady state inputs of the deposition apparatus 10 (e.g., pressures, gas flows, etc.), and auxiliary jet flows to further direct the coating stream 69 or deflected undeposited ingot material, for example.

In one example, the work pieces 12 are paired turbine airfoil components, such as a pair of cast vane airfoils secured to a common platform section. The coating device 52 provides the benefit of depositing a strong and durable coating on the paired turbine airfoil components, which includes a variety of transversely oriented and non-line of sight surfaces on the common platform section and at the radius between the airfoils and the common platform section. In a further example, the coating device 52 may be used to deposit the coating on non-line-of-sight surfaces between the pair of cast vane airfoils, which may only be fractions of an inch apart. That is, the coating device 52 may be aimed such that the coating stream 69 flows between the pair of cast vane airfoils.

FIG. 4 illustrates another example coating device 152 that is similar to the coating device 52 of the previous example and may be used in the deposition apparatus 10. In this disclosure, like reference numerals designate like elements where appropriate, and reference numerals with the addition of one-hundred or multiples thereof may designate modified elements. The modified elements incorporate the same benefits of the corresponding modified elements, except where stated otherwise. A nozzle portion 156 of the coating device 152 includes a funnel 166 having a top wall 113 that extends between the outlet orifice 68 and the sloped walls 74. For example, the top wall 113 is planar and is approximately perpendicularly oriented relative to the planar side walls 72 of the crucible portion 54.

As may be appreciated, the carrier gas 65 and entrained ingot material flowing through the flow passage 62 may impinge upon the top wall 113 before exiting through the outlet orifice 68 to produce random collisions among the particles within the coating stream 69.

FIG. 5 illustrates another example coating device 252 that is similar to the coating device 52 of the previous example and may be used in the deposition apparatus 10. In this example, a nozzle portion 256 of the coating device 252 includes a funnel 266 (in the sense that the carrier gas 65 and entrained ingot material will flow along a sloped path) but does not include the sloped walls 74 as in the previous example. That is, the funnel 266 only includes a top wall 213 extending between the outlet orifice 68 and the planar side walls 72 of the crucible portion 54. The top wall 213 is may be planar and may be approximately perpendicularly oriented to the planar side walls 72. The carrier gas 65 and entrained ingot material flowing through the flow passage 62 may impinge upon the top wall 213 before exiting through the outlet orifice 68 to produce random collisions among the particles within the coating stream 69.

Although a combination of features is shown in the illustrated examples, not all of them need to be combined to realize the benefits of various embodiments of this disclosure. In other words, a system designed according to an embodiment of this disclosure will not necessarily include all of the features shown in any one of the Figures or all of the portions schematically shown in the Figures. Moreover, selected features of one example embodiment may be combined with selected features of other example embodiments.

The preceding description is exemplary rather than limiting in nature. Variations and modifications to the disclosed examples may become apparent to those skilled in the art that do not necessarily depart from the essence of this disclosure. The scope of legal protection given to this disclosure can only be determined by studying the following claims.

What is claimed is:

1. A coating device for use with an electron beam vapor deposition apparatus, comprising:
a crucible portion having a gas inlet port, a heating zone for presenting a source coating material to be heated, and a flow passage exposed to the heating zone and fluidly connected with the inlet port; and
a nozzle portion including an outlet orifice fluidly connected with the flow passage for jetting a coating stream from the coating device.

2. The coating device as recited in claim 1, wherein the nozzle portion includes a funnel through which the outlet orifice extends.

3. The coating device as recited in claim 1, wherein the outlet orifice has a rectilinear cross-section.

4. The coating device as recited in claim 3, wherein the rectilinear cross-section is polygonal.

5. The coating device as recited in claim 3, wherein the rectilinear cross-section has an aspect ratio that is greater than one.

6. The coating device as recited in claim 3, wherein the rectilinear cross-section includes at least four sides.

7. The coating device as recited in claim 1, wherein the crucible portion includes planar side walls, and the nozzle portion includes a planar top wall perpendicularly oriented relative to the planar side walls and sloped walls extending from the planar top wall, the outlet orifice extending through the planar top wall.

8. The coating device as recited in claim 1, wherein the crucible portion includes planar side walls, and the nozzle portion includes at least one sloped wall extending between the planar side walls and the outlet orifice.

9. An electron beam vapor deposition apparatus comprising:
a coating chamber;
a coating zone within the coating chamber;
at least one electron beam source for evaporating a source coating material;
a gas source for selectively providing a carrier gas; and
a coating device including a crucible portion and a nozzle portion, the crucible portion having a gas inlet port fluidly connectable with the gas source, a heating zone for presenting the source coating material to be heated, and a flow passage exposed to the heating zone and fluidly connected with the inlet port, the nozzle portion including an outlet orifice fluidly connected with the flow passage for jetting a coating stream of the source coating material and the carrier gas toward the coating zone.

10. The coating device as recited in claim 9, wherein the nozzle portion includes a funnel through which the outlet orifice extends.

11. The electron beam vapor deposition apparatus as recited in claim 9, further comprising an ingot as the source coating material, the ingot including at least one of yttria, gadolinia, or zirconia.

12. The coating device as recited in claim 9, wherein the outlet orifice has a rectilinear cross-section having an aspect ratio that is greater than one.

13. The coating device as recited in claim 12, wherein the rectilinear cross-section includes at least four sides.

14. The coating device as recited in claim 9, wherein the crucible portion includes planar side walls, and the nozzle portion includes a planar top wall perpendicularly oriented relative to the planar side walls and sloped walls extending from the planar top wall, the outlet orifice extending through the planar top wall.

15. The coating device as recited in claim 9, wherein the crucible portion includes planar side walls, and the nozzle portion includes at least one sloped wall extending between the planar side walls and the outlet orifice.

16. A method for use with an electron beam vapor deposition apparatus, comprising:
emitting electron beams from an electron beam source onto a source coating material within a crucible portion of a coating device to evaporate the source coating material;
entraining evaporated source coating material in a carrier gas to provide a coating stream; and
jetting the coating stream toward a coating zone from an outlet orifice of a nozzle portion of the coating device.

17. The method as recited in claim 16, wherein the entraining includes evaporating the source coating material to produce vaporized source coating material and establishing a flow of the carrier gas adjacent to the source coating material.

18. The method as recited in claim 16, wherein the jetting includes establishing a flow of the coating stream through a funnel of the coating device, the funnel including the outlet orifice.

19. The method as recited in claim 16, wherein the jetting includes establishing random collisions among the evaporated source coating material within the coating stream.

20. The method as recited in claim 19, further comprising selecting the outlet orifice to include a rectilinear cross-section to establish the random collisions.
